(19) United States
(12) Patent Application Publication
(10) Pub. No.: US 2024/0040934 A1
(43) Pub. Date: Feb. 1, 2024

(54) TRANSDUCER ELEMENT BASED ON DIALECTRIC ELASTOMERS, METHOD FOR PRODUCING A TRANSDUCER ELEMENT, AND HYBRID GRIPPER

(71) Applicant: Fraunhofer-Gesellschaft zur Förderung der angewandten Forschung e.V., München (DE)

(72) Inventors: Sebastian Riess, Darmstadt (DE); Tim Noack, Darmstadt (DE)

(21) Appl. No.: 18/258,520

(22) PCT Filed: Dec. 17, 2021
(86) PCT No.: PCT/EP2021/086661

§ 371 Date: Jun. 20, 2023

(30) Foreign Application Priority Data
Dec. 21, 2020 (DE) 10 2020 216 411.8

(51) Int. Cl. H10N 30/87; B65G 47/91; H10N 30/50; B25J 15/06; H10N 30/85; H10N 30/05

(52) U.S. Cl. CPC H10N 30/871; B65G 47/91; H10N 30/50; B25J 15/0608; H10N 30/85; H10N 30/05

(57) ABSTRACT

Transducer element (1) based on dielectric elastomers, including a carrier board (2), wherein the carrier board has first contact surfaces (6) which are conductively connected to a first connector contact (7), and second contact surfaces (9) which are conductively connected to a second connector contact (10). The transducer element (1) also includes at least one elastomer film (3), consisting of a dielectric material, at least two electrodes (4), wherein the electrodes are at least partially air-permeable and each have at least one contact surface (15) for conductively connecting to the first or second contact surfaces of the carrier board. The at least two electrodes (4) and the at least one elastomer film (3) are arranged on the carrier board (2) so that a stack is formed, in which the electrodes (4) and elastomer films (3) are arranged alternately, and the electrodes (4) are conductively connected alternately to the first contact surfaces (6) and the second contact surfaces (9) of the carrier board (2).

### CROSS REFERENCE TO RELATED APPLICATIONS

This application is a national stage entry of PCT/EP2021/086661, internationally filed on Dec. 17, 2021, which claims priority to German Application No. 10 2020 216 411.8, filed Dec. 21, 2020, both of which are incorporated herein by reference in their entirety.

### TECHNICAL FIELD

The invention relates to a transducer element based on dielectric elastomers. Furthermore, a method is described for producing such a transducer element, and a hybrid gripper used in this method.

### BACKGROUND

Dielectric elastomers are material systems from the group of electroactive polymers which deform under the influence of electrical stimulation. A dielectric elastomer transducer element (DE transducer element), which converts electrical energy into mechanical work or also converts mechanical work into electrical energy, i.e. can act both as an actuator and also a generator or sensor, is basically constructed like an electrostatic capacitor: a flexible, but incompressible elastomer film is arranged between two electrodes. If voltage is applied to the electrodes they attract each other electrostatically and the elastomer film is reversibly deformed. The elastomer film is compressed and expands in lateral direction. Conversely, such an element consisting of electrodes and elastomer film can also be used as a pressure or force or position sensor, as changing the distance between the two electrodes and the associated deformation of the elastomer also changes the capacitance of the capacitor.

One form of such a transducer is a stacked actuator, in which a plurality of planar actuators consisting of electrodes and elastomer are stacked in order to achieve greater travel distances when voltage is applied. Such transducers are known in the prior art. For example patent specification EP 2 630 674 B1 proposes a DE transducer element with recesses in the metallic electrodes which allow the lateral expansion of the elastomer to be minimized when the element is compressed, which results in improved operating behavior at higher vibration frequencies. However, such transducer elements cannot yet be produced on a large scale, as the layer thickness of the electrodes and elastomer films are usually in the Linn range and sometimes hundreds of these layers need to be stacked precisely which is difficult to automate.

### SUMMARY

An objective of the present patent application is therefore to propose an assembly of a transducer element based on dielectric elastomers which can be implemented industrially in a simple manner, as well as a method for producing such a transducer element. Furthermore, the structure of a hybrid gripper is described which is suitable for executing the method.

The objective is achieved by a transducer element according to the independent claim 1. A method for producing such a transducer element is described in claim 11 and a hybrid gripper for use in this method is described in claim 18. Further embodiments are given in the dependent claims.

A transducer element based on dielectric elastomers comprises
a. a carrier board, wherein the carrier board has first contact surfaces connected conductively to a first connector contact and second contact surfaces connected conductively to a second connector contact,
b. at least one elastomer film, consisting of a dielectric material,
c. at least two electrodes, wherein the electrodes are at least partly air-permeable and each have at least one contact surface for connecting conductively to the first or second contact surfaces of the carrier board,
d. wherein the at least two electrodes and the at least one elastomer film are arranged between on the carrier board so that a stack is formed in which the electrodes and elastomer films are arranged alternately, and the electrodes are conductively connected alternately to the first contact surfaces and the second contact surfaces of the carrier board.

The layers of electrodes and elastomer films are applied to a carrier board, wherein the electrodes are connected alternately to the two different contact surfaces of the carrier board, for example by spot welding. In this way, the electrodes are mechanically fixed together with the elastomer films in between and can be contacted electrically in a simple manner. For this purpose, the carrier board has connector contacts which are connected via conductor tracks to the contact surfaces, so that opposing voltages can be applied to the electrodes or a sensor evaluation unit can be connected to the electrodes.

If more than the at least two electrodes and at least one elastomer film are used, the contact surfaces of the electrodes continue to be connected alternately to the two contact surfaces of the carrier board. A simple way of achieving this is to weld the contact surfaces of the uppermost electrode to the contact surfaces of the electrode which is located two layers further down. If the electrodes stacked on the carrier board are counted from the bottom from 1 to n, the first electrode being connected to the first contact surfaces of the carrier board and the second electrode being connected to the second contact surfaces, the contact surfaces of the nth electrode are thus connected respectively to the contact surfaces of the (n-2)th electrode. In this way, only the carrier board has to be connected to a voltage source or evaluation unit for measuring the capacitance, and a time-consuming contacting of the individual electrodes is not necessary.

Generally, the stack of electrodes and elastomer films is formed such that one elastomer film is placed between two electrodes respectively. In some circumstances however it may be appropriate if one elastomer film is only in contact with one electrode, i.e. is used as the first or last layer of a stack.

The arrangement of the actual dielectric elastomer transducer as a stack on the carrier board fixes it mechanically and ensures a stable stack, thereby enabling simpler manufacturing of the transducer element. As the positions of the contact surfaces in the stack are predefined, this also enables automated stacking and welding of the components.

The elastomer films consist of layers with thicknesses in the Linn range made of materials such as silicones, acrylics or polyurethanes for example. In general, a material used as an elastomer film should have a high dielectric constant, a low modulus of elasticity and a high dielectric strength.

The electrodes are made from a material with good electrical conductivity and are designed to be at least partly permeable. The electrodes also have layer thicknesses in the Linn range. Suitable materials are metals such as copper, nickel, steel or aluminum, which have a high modulus of elasticity compared to the elastomer used. In particular, in the surface of the electrode, i.e. perpendicular to the thickness of the transducer element, the electrodes are therefore rigid. Ferromagnetic materials are particularly advantageous for the method also described.

By making the electrodes at least partially air-permeable, for example by having holes in the electrodes, vacuum grippers can be used in the production of the transducer element, which can position a composite of an electrode and an elastomer film at once, wherein the elastomer film is located under the electrode and can be suctioned through by it. Furthermore, the air permeability of the electrode can be achieved by recesses, thereby achieving a further advantageous effect. In the application of the transducer element when force is applied in thickness direction the elastomer films can penetrate into these recesses so that the whole transducer element is compressed in thickness direction, but the expansion of the elastomer to the sides is limited. In this way the elastomer is less restricted in its expansion by the rigid electrodes.

Structuring the electrodes in this way is possible for example by providing recesses in the form of troughs. These are preferably formed on at least one side of the electrode facing the elastomer film so that the latter can expand into the troughs when under pressure.

In a further embodiment the electrodes are perforated. This produces air permeability and the already described positive effect of additional expansion space for the elastomer films. Perforation of the electrodes can also be combined with other structurings of the electrodes.

The carrier board is used not only for mechanically fixing and contacting the stack of dielectric elastomers and electrodes, but can also form a shielding surface for shielding the transducer element at the bottom. For this purpose, the carrier board can have a third connector contact which is connected to the shielding surface.

A shield board can form the termination of the stack at the top. This board is also used for shielding the transducer element and can therefore also be connected to the carrier board. By shielding the transducer element the latter is not negatively affected by external interference, and when used as a sensor the precision of the capacitance measurement can be increased.

The carrier board can be configured such that it has a fourth connector contact and the shield board such that it has a connector contact, which can be connected to the carrier board so that the contacting of the shield board is also achieved via the carrier board. In this way, the complete electrical contacting of the transducer element is possible via the carrier board.

The carrier and shield board can have a square or approximately square base shape. With such a square base shape, two opposite corners of the carrier board can form the first contact surfaces, while the two other opposite corners form the second contact surfaces. In this way, the contact surfaces are separated well spatially and easy to contact or to weld to other contact surfaces. By using two contact surfaces there is also a certain redundancy regarding the connection to the electrodes.

The shape of the carrier and shield boards is not restricted to squares or even just to quadrilateral shapes. Instead, the components can have a base surface of any geometric shape. In this case however the contact surfaces should also be separated from one another spatially such that contact surfaces of electrodes can be connected to them easily and without problems with electrical conductivity. By selecting the shape of a base surface of the carrier board the form of the transducer element is determined and can thus be adapted to different purposes.

The electrodes can also have spatially separated contact surfaces. When using square carrier and shield boards square electrodes are also suitable for example, the contact surfaces of which are arranged at two opposite corners of the electrodes. When stacking the electrodes and elastomer films the electrodes configured in this way can be easily rotated by 90° in order to change between contact with the first contact surfaces and contact with the second contact surfaces of the carrier board. The fact that the electrodes can have two spatially separate contact surfaces, in conjunction with the spatially separate contact surfaces of the carrier board, can in turn ensure a certain redundancy in the voltage supply/connection of the electrodes to an evaluation device. The contact surfaces can be configured as tongues for example. In the case of high stacks with multiple layers of electrodes and elastomer films, embodiments of the contact surfaces as tongues are also possible which can compensate for different heights by deformation.

It is possible to configure the carrier and shield boards as flexible circuit boards. This makes it possible to use the transducer element on curved surfaces.

The carrier board can also be segmented. In this way for example a plurality of sensor elements can be configured on one carrier board so that entire sensor arrays can be assembled on one board. For this purpose, further contacts are needed on the carrier board.

It is also possible that the carrier board, in particular in the areas around the stack of electrodes and elastomers, but also on its underside, is designed to accommodate electronic components. These can be components for evaluating the capacitance of the transducer element, but also components for controlling the element as an actuator.

A method for producing a described transducer element comprises the following steps:
positioning the carrier board on a counter electrode suitable for spot welding,
picking up a first electrode with a hybrid gripper, wherein the hybrid gripper comprises an electromagnet,
positioning the first electrode over the carrier board,
spot welding the first contact surfaces of the carrier board to the contact surfaces of the first electrode,
picking up an elastomer film with the hybrid gripper, wherein the hybrid gripper is configured with a vacuum connection so that the elastomer film can be suctioned,
positioning the elastomer film over the first electrode,
picking up a second electrode with the hybrid gripper,
positioning the second electrode over the elastomer film,
spot welding the second contact surfaces of the carrier board to the contact surfaces of the second electrode.

By way of these method steps, the production of a transducer element can also be automated for industrial applications with a suitable hybrid gripper. By means of automatic positioning a sufficiently high degree of precision is achieved, even when applying thin layers. Reliable conductive connections are formed by welding the contact surfaces.

By picking up a shield board with the hybrid gripper and placing it on the second electrode, the transducer element can be closed off at the top in order to produce a shielded transducer element.

As the electrodes are configured to be at least partially air-permeable, a hybrid gripper equipped with an electromagnet and vacuum connection can pick up an electrode and an elastomer film at the same time by suctioning the film through the magnetically picked up electrode via the vacuum connection. This has the advantage that it is possible to combine the steps in which an elastomer film and a second electrode are picked up and placed. A further advantage is that the elastomer film can be already positioned relative to the electrode before it is picked up by the hybrid gripper and fixed in place by the vacuum. The assembly of a stack is thereby simplified and errors can be avoided.

The method steps of picking up and positioning the elastomer films and picking up, positioning and welding the electrode, in particular the simultaneous picking up, positioning and welding of elastomer film and electrodes, can be repeated as often as desired to produce transducer elements with any number of layers. The contact surfaces of the newly added n-th electrodes are welded here to those of the (n-2)th electrode. By making a suitable choice for the shape of the transducer element the electrodes newly added to a stack always have to be placed in the same positions and simply rotated to produce the different contact paths. In this case, the positions of the necessary spot welds also remain the same so that no additional effort is required for the automation.

In a particularly simple case, both the carrier and shield boards and also the electrodes have square base shapes with associated contact surfaces at opposite corners of the square. In this case each second electrode is welded rotated by 90′ to produce a conductive connection between the first contact surfaces of the carrier board and the first, third and every other odd electrode, while the second contact surfaces are connected to the second, fourth and every even electrode.

A hybrid gripper suitable for performing this method comprises
an electromagnet for picking up the electrodes,
a vacuum connection for picking up the carrier board, the shield board and the elastomer film through the at least partially air-permeable electrode and
one or more spot welding electrodes for welding the contact surfaces.

Furthermore, such a hybrid gripper can comprise a rotating blade which is configured to punch out an elastomer film from a continuous film strip. This blade can be configured to be heatable. The punched out elastomer film is then fixed by vacuum and is thus automatically positioned correctly on the gripper. Supplying the film in this way is less complex than providing already punched out films. It is particularly advantageous if the punching out of the elastomer film takes place with an already picked up electrode. Furthermore, it is also possible for the electrodes to be punched out in a similar way or also the electrodes and elastomer films.

A hybrid gripper, which is suitable for performing the method for producing a transducer element, can be attached to a suitable kinematics or a pick-and-place robot and moved via the latter in order to effectively execute the method steps. Thus the method can be fully automated.

The described embodiments of the subject-matters of the present application can thereby be used both individually and in combination in order to achieve additional effects and thus provide a transducer element which is simple to manufacture based on dielectric elastomers, a method for producing such a transducer element as well as a hybrid gripper used for this method.

### BRIEF DESCRIPTION OF THE DRAWINGS

The aspects mentioned and also further aspects of the invention will be apparent from the detailed description of the exemplary embodiments, which are given with reference to the following drawings, in which:

FIG. 1a is a perspective schematic view of a transducer element,

FIG. 1b is a schematic side view of the transducer element,

FIG. 2a shows a schematic representation of a carrier board,

FIG. 2b shows a schematic representation of an electrode,

FIG. 2c shows a schematic representation of a shield board,

FIG. 2d shows a further schematic representation of an electrode,

FIG. 3 represents the sequence of the method for producing a transducer element,

FIG. 4 is an exploded view of a hybrid gripper in use in the method and

FIG. 5 shows two cross-sectional representations of the hybrid gripper.

In the following, the claimed subject-matters will be explained in more detail based on the accompanying drawings. Here, the same reference signs are used for the same elements.

### DETAILED DESCRIPTION

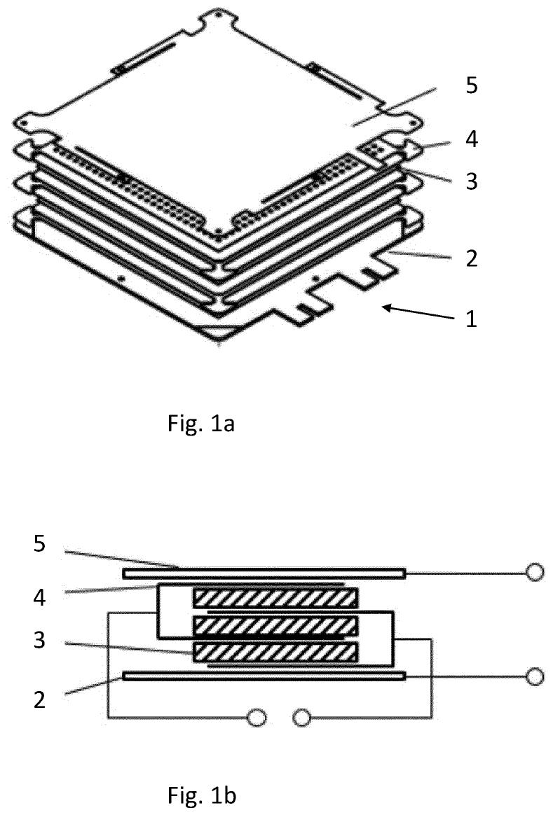

FIG. 1a shows the structure of a transducer element 1. It consists of a carrier board 2, a shield board 5 and a stack of electrodes 4 and elastomer films 3 arranged in between. In the specifically shown case the stack consists of five electrodes and four layers of elastomer film. It consists of a transducer element with an approximately square base shape. The contact surfaces of the electrodes are shown clearly. The latter are arranged alternately, as each electrode is rotated 90° relative to the electrode below it. The connector contacts of the carrier board are also shown.

FIG. 1b shows a schematic side view of a transducer element. This representation shows the mode of operation of a transducer element. In contrast to FIG. 1a the transducer element 1 in FIG. 1b consists of four electrodes 4 and three elastomer films 3 arranged in between. FIG. 1b also shows how the electrodes 4 are each connected alternately to a voltage source. By applying voltage to the electrodes 4 an electrostatic pressure acts on the latter. The electrodes 4 attract one another, the elastomer films 3 are compressed and the whole stack thus has a reduced vertical extension. Likewise, the transducer element can be compressed vertically by external forces. The distances between the electrodes change and the elastomer films are pressed together. In this way the capacitance of the transducer element, which can be measured by an evaluation unit, changes. In this way, the transducer element can be used as a pressure, force or displacement sensor. The carrier board 2 and the shield board 5 can also be connected to one another conductively and for example to ground, in order to shield the transducer element externally and to increase the accuracy of a capacitance measurement when the transducer element 1 is used as a sensor.

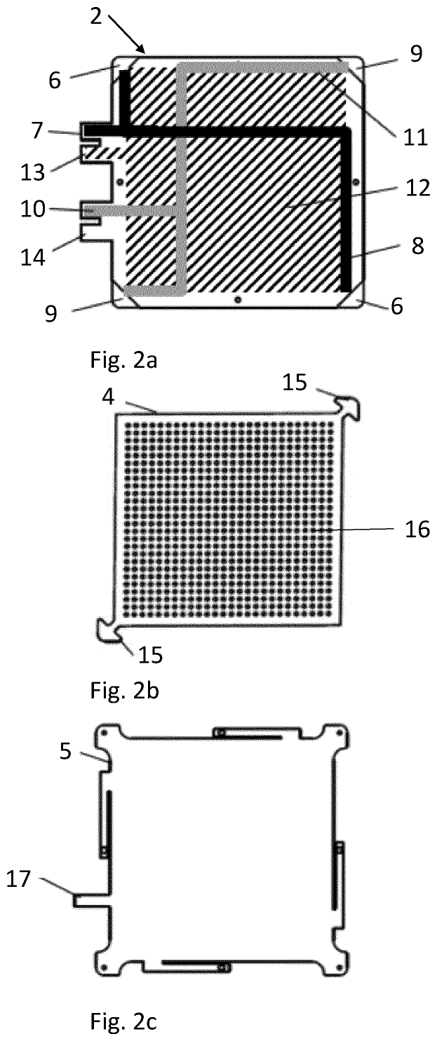

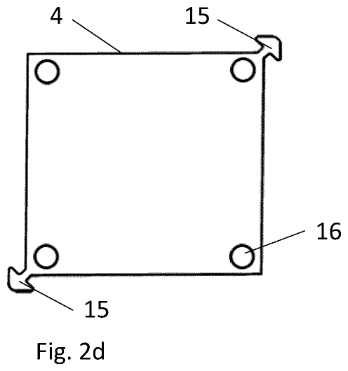

FIG. 2a, FIG. 2b and FIG. 2c show the individual components of the transducer element in more detail. FIG. 2a shows a possible embodiment of a carrier board 2 with a square base surface. It has four contact surfaces at its corners, where the contact surfaces 6, 9 arranged at opposite corners together form first contact surfaces 6 for connecting to a first electrode and second contact surfaces 9 for connecting to a second electrode. The first contact surfaces 6 are connected via a conductor track 8 to a first connector contact 7 which is arranged on the edge of the carrier board 2. The second contact surfaces 9 are connected via a conductor track 11 to a second connector contact 10 which is arranged on the edge of the carrier board 2. The majority of the carrier board 2 is taken up by a shielding surface 12, which is connected to a third connector contact 13. The fourth connector contact 14 is used for connecting the carrier board 2 to a shield board 5.

The carrier board, as shown in FIG. 2a, can be a conventional circuit board, but it can also be a flexible circuit board. The use of a flexible circuit board makes it possible for example to attach the transducer element to curved surfaces. FIG. 2a shows one of the simplest embodiments of the carrier board. It can also be configured so that it can accommodate further electronic components. For this purpose it can also be printed on both sides. Additional electronic components which can be mounted on the carrier board are in particular components for controlling the electrodes in actuator operation or components which evaluate the capacitance of the transducer element and thus enable sensor operation. If these components are installed directly on the carrier board, the transducer element and its connection to the environment can be configured in a very space-saving manner.

A further option is segmentation of the carrier board 2, in which a circuit board is divided into several segments, which are each constructed as in FIG. 2a. In this way for example a plurality of sensor elements can be arranged on a circuit board, which enables a simple assembly of sensor arrays.

FIG. 2b shows a possible embodiment of an electrode 4. The electrode 4 consists of an electroconductive material, preferably a metal layer. It also has a square base surface, in which the contact surfaces 15 are formed as projecting, arrow-like tongues in two opposite corners. This enables simple welding of the contact surfaces 15 to the first contact surfaces 6 or, when the electrode is rotated by 90°, to the second contact surfaces 9 of the carrier board 2. Thus the electrodes 4 can be stacked onto the carrier board 2 and connected to the latter conductively with little effort. In the case of higher stacks longer tongues or tongues which are configured to compensate for height differences may also be advantageous.

The electrode 4 has a perforation 16. This is used on the one hand to give the elastomer films 3 arranged between the electrodes 4 space into which they can expand in the event of vertical compression. In this way the planar expansion of the elastomer films 3 can be reduced and the electrodes do not need to be expandable to cover the resulting larger area of the elastomer films 3, which makes it possible to make the electrodes from rigid, metal materials. By avoiding the planar expansion of the surfaces the response or operating behavior of the transducer element is also improved in specific frequency ranges, as there is less loss of power as a result of the deformation of the edge areas of the elastomer films 3. On the other hand, the perforation 16 is also useful for producing a transducer element 1, as it makes the electrode at least partly air-permeable and thus make it possible to use a vacuum gripper to pick up an elastomer film 3 and an electrode 4 at the same time. The elastomer film 3 is thereby suctioned through the electrode 4. This makes it possible to align the elastomer film 3 and electrode 4 with one another even before they are picked up by a gripper and to place them as a unit on a stack of a transducer element 1. It is not necessary to perform a time-consuming precise positioning of the individual components on the stack. This method and a hybrid gripper suitable for this method are described in more detail in later sections.

FIG. 2d shows an alternative embodiment of the electrode 4. In this case the air-permeability is achieved by a perforation 16 in the form of large holes in the corners of the electrode 4. In this embodiment, the effect of the holes as an expansion space for the elastomer film 3 is limited, but this can be compensated for by additional structuring of the electrode.

A simple shield board 5 is shown in FIG. 2c. This is used for shielding the transducer element at the top. For this purpose the shield board 5 is used as a shielding surface, which can be connected to the fourth connector contact 14 of the carrier board via a connector contact 17. The shielding board 5 can also be a flexible circuit board. The use of a flexible circuit board makes it possible for example to attach the transducer element to curved surfaces. The tongues and bores also shown in FIG. 2c (also shown in FIG. 2a) are used for mechanically fixing the shield board against the carrier board. The tongues are therefore configured to be able to compensate for height differences in order to also allow for transducer elements with multilayered, high stacks of electrodes and elastomer films.

FIG. 2a/b/c/d show the components of a transducer element with a simple square base shape. However, the carrier board 2, the electrodes 4 and the shield board 5 can also have any other geometries in order to be adapted to special conditions or requirements.

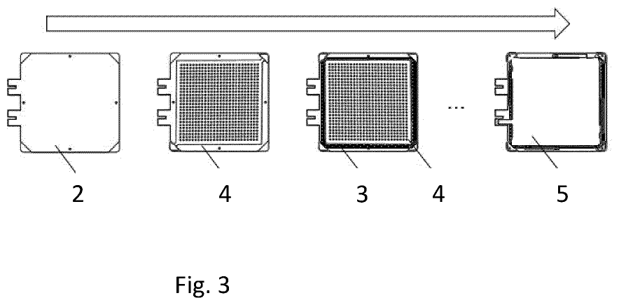

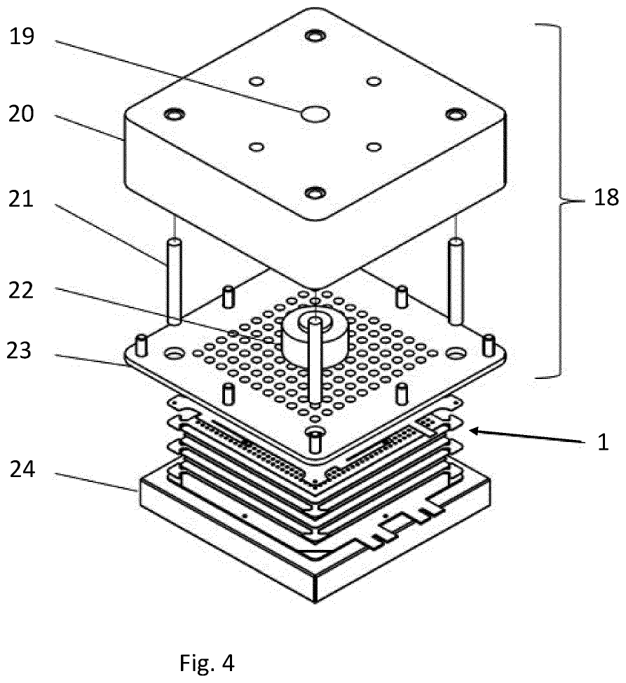

FIG. 3 represents the sequence of a method for producing a transducer element. The arrow indicates the chronology of the individual method steps. In a first step a carrier board 2 is positioned on a counter electrode 24 suitable for spot welding (shown in FIG. 4).

In a second step a first electrode 4 is positioned on this carrier board 2. For this purpose, the electrode 4 is picked up by the electromagnet 22 of a hybrid gripper 18. The contact surfaces of this first electrode are then welded to the first contact surfaces 6 of the carrier board 2.

In a third step an elastomer film 3 is picked up. A hybrid gripper 18 with a vacuum connection 19 is particularly suitable for this. The elastomer film is placed on the first electrode 4. A second electrode 4 is picked up and placed on the elastomer film 3 rotated 90° to the first electrode 4. By using a suitable hybrid gripper 18 these substeps can be carried out in a single method step. For this purpose, the second electrode 4 is picked up by an electromagnet 22 and at the same time the elastomer film 3 is suctioned through the perforation of the electrode 4. Both layers can thus be positioned at once on the first electrode 4. Thus, the position of the elastomer film 3 does not have to be checked when positioning the second electrode 4, and a possible displacement of the elastomer film 3 between its application and fixing by the second electrode 4 can be prevented. For this purpose the elastomer film 3 can be positioned relative to the second electrode 4 before both are picked up together by the hybrid gripper 18. Once the elastomer film 3 and second electrode 4 have been placed on the stack, the contact surfaces 15 of the second electrode 4 are welded to the second contact surfaces 9 of the carrier board.

Picking up and placing a layer of elastomer film 3 and second electrode 4, in particular picking up and placing elastomer film 3 and second electrode 4 at the same time, can now be repeated as often as desired until a desired stack height is achieved. Here each newly added electrode 4 is applied rotated 90° relative to the preceding electrode 4 and welded respectively to the electrode 4 lying below the preceding one. It is thus achieved that all electrodes in odd-numbered layers of the stack are conductively connected to the first connector contact 7 of the carrier board 2 and all electrodes in even-numbered layers of the stack are conductively connected to the second connector contact 10 of the carrier board 2.

In a final step the shield board 5 is applied to the stack and the shield contact 17 is connected to the fourth connector contact 14 of the carrier board.

The described method has several advantages over a conventional method, in which the layers are stacked and screwed together by hand. On the one hand it can be automated with a suitable hybrid gripper 18. The gripper can also handle very thin layers precisely and position them in a reproducible manner. If elastomer film 3 and electrode 4 are picked up together by the hybrid gripper 18, there is no need to align the two components relative to one another on the stack, thereby eliminating another source of error.

The spot welding used in this method has the advantage over conventionally used screw connections of taking up less space, and without additional complex components producing a reliably conductive connection between the electrodes 4 and connections 7 and of the carrier board 2.

A hybrid gripper 18 suitable for performing the described method is shown in FIG. 4. The hybrid gripper 18 is adapted here to the structure of a transducer elements as in FIG. 1 and FIG. 2. Other geometries of the transducer element would also require adapted geometries of the hybrid gripper 18. The hybrid gripper 18 consists of a housing 20 with a vacuum connection 19, an electromagnet 22 and a grid 23. Spot welding electrodes 21 are attached to the four corners of the housing 20, the positions of which are matched to the positions of the contact surfaces 6, 9 and 15 of the carrier board 2 and the electrodes 4. FIG. 4 shows the hybrid gripper 18 in use, the depiction also shows the transducer element 1 and a counter electrode 24 suitable for spot welding.

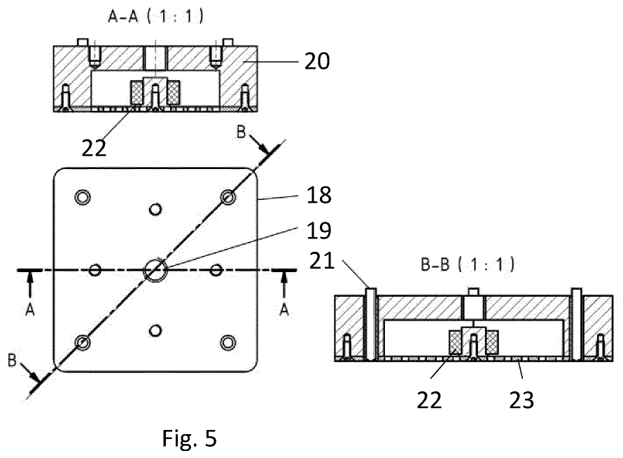

FIG. 5 shows sections through the hybrid gripper 18. In section A-A it can be seen that the housing 20 is hollow so that a vacuum can be generated inside the gripper 18 via the central vacuum connection 19. Components such as an elastomer film 3 can thus be suctioned through the grid 23 and fixed. At the same time the electromagnet 22 enables ferromagnetic components, such as the metallic electrode 4, to be picked up. The section along the B-B axis also comprises the spot welding electrodes arranged at opposite corners which are used to fix the electrodes 4 with permanent connections.

The hybrid gripper 18 can also be provided with a rotating blade. This can be configured to be heatable. With a rotating blade elastomer films 3 can be punched directly out of a continuous film strip and picked up by the hybrid gripper 18. This can be particularly useful in the case of thin layer thicknesses of the elastomer films 3, as the previous punching out and preparation as a stack of elastomer films is prone to errors in these cases. A complex positioning process of the gripper for picking up the elastomer film 3 is also omitted here. If the rotating blade is configured so that the hybrid gripper 18 can punch out an elastomer film 3 with an already picked up electrode 4, it can be punched out and fixed in the correct position so that the elastomer film 3 and electrode 4 can be applied jointly to the stack.

To enable automation of the method for producing a transducer element, the hybrid gripper 18 should be configured so that it can be moved with sufficient precision via suitable kinematics. For example a pick-and-place robot is suitable for this purpose which can move up to the various positions for picking up electrodes, elastomer films, carrier and shield board as well as the position of a counter electrode for spot welding.

To automate the method an embodiment is therefore particularly suitable in which the hybrid gripper 18 can move up to three positions via kinematics, at which it can pick up carrier boards 2, electrodes 4 and shield boards 5 respectively with the electromagnet 22. At a fourth position an endless film is supplied from which it punches out an elastomer film 3 and fixes it by vacuum. All components are stacked and welded at a fifth position on a counter electrode 24.

The exemplary embodiments shown here are not limiting. In particular, the features of these exemplary embodiments can be combined with one another to achieve additional effects. For the person skilled in the art it is obvious that modifications can be made to these exemplary embodiments without departing from the fundamental principles of the subject-matter of this patent application, the scope of which is defined in the claims.

1. A transducer element based on dielectric elastomers, comprising
a carrier board, wherein the carrier board comprises first contact surfaces 464, which are conductively connected to a first connector, and second contact surfaces, which are conductively connected to a second connector contact,
at least one elastomer film, consisting of a dielectric material,
at least two electrodes, wherein the electrodes are at least partially air-permeable and each have at least one contact surface for conductively connecting to the first or second contact surfaces of the carrier board,
wherein the at least two electrodes and the at least one elastomer film are arranged on the carrier board so that a stack is formed, in which the electrodes and elastomer films are arranged alternately, and the electrodes are conductively connected alternately to the first contact surfaces and the second contact surfaces of the carrier board.

2. The transducer element according to claim 1, characterized in that the at least two electrodes are structured on at least one side so that they have recesses in the form of troughs.

3. The transducer element according to claim 1, characterized in that the at least two electrodes are perforated.

4. The transducer element according to claim 1, characterized in that the carrier board has a shielding surface, which is conductively connected to a third connector contact.

5. The transducer element according to claim 1, further comprising a shield board, which terminates the stack of at least two electrodes and at least one elastomer film on a side facing away from the carrier board.

6. The transducer element according to claim 5, characterized in that the carrier board has a fourth connector contact and the shield board has a shield contact for connecting to the fourth connector contact.

7. The transducer element according to claim 5, characterized in that the carrier boardand the shield board have a square or approximately square base surface and the carrier board has first contact surfaces on two opposite corners and second contact surfaces on the two other opposite corners of the square or approximately square base surface.

8. The transducer element according to claim 5, characterized in that the carrier board and the shield board have a base surface of any geometric shape and the first contact surfaces and the second contact surfaces of the carrier board are spatially separated from one another.

9. The transducer element according to claim 1, characterized in that the at least two electrodes each have two spatially separated contact surfaces.

10. The transducer element according to claim 5, characterized in that the carrier board and/or the shield board are configured as flexible circuit boards.

11. The transducer element according to claim 1, characterized in that the carrier board is segmented.

12. The transducer element according to claim 1, characterized in that the carrier board is configured to accommodate electronic components.

13. A method for producing a transducer element, the method comprising the following steps:
positioning a carrier board on a counter electrode suitable for spot welding, so that contact surfaces of the carrier board are in contact with the counter electrode,
picking up a first electrode with a hybrid gripper, wherein the hybrid gripper has an electromagnet,
positioning the first electrode over the carrier board,
spot welding first contact surfaces of the carrier board to contact surfaces of the first electrode,
picking up an elastomer film with the hybrid gripper, wherein the hybrid gripper is configured to have a vacuum connection, so that the elastomer film can be suctioned,
positioning the elastomer film over the first electrode,
picking up a second electrode with the hybrid gripper,
positioning the second electrode over the elastomer film,
spot welding second contact surfaces of the carrier board to contact surfaces of the second electrode.

14. The method according to claim 13, additionally comprising the steps:
picking up a shield board with the hybrid gripper, and placing the shield board on the second electrode.

15. The method according to claim 13, characterized in that the second electrode and the elastomer film are picked up and positioned at the same time by the hybrid gripper, wherein the elastomer film is suctioned by the hybrid gripper through the electrode.

16. The method according to claim 13, characterized in that the steps of picking up and positioning the elastomer film and the second electrode are repeated until a desired stack height is achieved and wherein contact surfaces of the newly added second electrodes are not welded to contact surfaces of a directly underlying electrode, but to those of the electrode below the directly underlying electrode in the stack.

17. The method according to claim 13, characterized in that the first electrode and the second electrode have a square base shape with contact surfaces on two opposite corners and are arranged in the stack rotated 90° relative to one another.

18. A hybrid gripper, for producing a transducer element, the hybrid gripper comprising
an electromagnet for picking up one or more at least partially air-permeable electrodes,
a vacuum connection for picking up a carrier board, a shield board and than one or more elastomer film through the one or more at least partially air-permeable electrode, and
one or more spot welding electrodes for welding contact surfaces.

19. A hybrid gripper according to claim 18, further comprising a rotating blade, which is configured to punch out the one or more elastomer film from a continuous film strip or the one or more at least partially air-permeable electrode.

20. A hybrid gripper according to claim 18, characterized in that the gripper is configured so that it can be moved via suitable kinematics or via a pick-and-place robot.
